(19) United States
(12) Patent Application Publication
(10) Pub. No.: US 2006/0261498 A1
(43) Pub. Date: Nov. 23, 2006

(54) Methods and apparatuses for encapsulating microelectronic devices

(75) Inventor: Stephen L. James, Boise, ID (US)

Correspondence Address: PERKINS COIE LLP;PATENT-SEA, PO BOX 1247, SEATTLE, WA, 98111-1247, US

(73) Assignee: Micron Technology, Inc., Boise, ID (US)

(21) Appl. No.: 11/130,890

(22) Filed: May 17, 2005

(51) Int. Cl. H01L 23/28

(52) U.S. Cl. 257/787

(57) ABSTRACT

Methods and apparatuses for encapsulating microelectronic devices are disclosed herein. In one embodiment, a method for encapsulating a microelectronic device having a microelectronic die attached to a substrate includes positioning the microelectronic die in a molding cavity having a first volume. The method also includes introducing a molding compound into the molding cavity to at least partially encapsulate the die. The method further includes reducing the volume of the molding cavity from the first volume to a second volume less than the first volume while the microelectronic die and the molding compound are in the molding cavity.

### TECHNICAL FIELD

The present invention is related to methods and apparatuses for packaging microfeature devices. More particularly, the invention relates to encapsulating microelectronic dies in the manufacturing of memory devices, microprocessors, and other types of microelectronic devices.

### BACKGROUND

Many packaged microelectronic devices have a substrate, a microelectronic die attached to the substrate, and a protective covering encasing the die. The protective covering is generally a plastic or ceramic compound that can be molded to form a casing over the die. The microelectronic die can be a memory device, a microprocessor, or another type of microelectronic assembly having integrated circuitry. Several types of packaged devices also include bond pads on the substrate that are coupled to the integrated circuitry of the die. The bond pads may alternatively be coupled to pins or other types of terminals that are exposed on the exterior of the microelectronic device for connecting the die to buses, circuits, and/or other microelectronic assemblies.

A significant limiting factor for manufacturing packaged microelectronic devices is encapsulating the die with the protective covering. The dies are sensitive components that should be protected from physical contact and environmental conditions to avoid damaging the die. The protective casing encapsulating the die, therefore, should seal the die from the environmental factors (e.g., moisture) and shield the die from electrical and mechanical shocks. Thus, the protective casing should not have any voids that may allow contaminants or environmental factors to contact and potentially damage the die.

One conventional technique for encapsulating the die is known as “transfer-molding,” which involves placing the die and at least a portion of the substrate in a cavity of a mold and then injecting a thermosetting material into the cavity. In one conventional arrangement shown in FIGS. 1A and 1B, for example, a molding tool 10 simultaneously encases a plurality of microelectronic devices 20. More specifically, FIG. 1A is a partially schematic cross-sectional view of the molding tool 10 and FIG. 1B is a top plan view of a portion of the molding tool 10. Referring to FIGS. 1A and 1B together, the molding tool 10 can include an upper plate 12 removably positioned on a lower plate 13 to define a plurality of substrate chambers 14, an upright pellet cylinder 30, and a plurality of channels 16 connecting the substrate chambers 14 to the cylinder 30. A cylindrical pellet 40 formed from an epoxy mold compound is positioned in the cylinder 30, and a plunger 50 moves upwardly within the cylinder 30 to transfer heat and exert pressure against the pellet 40. The heat and pressure from the plunger liquefy the mold compound of the pellet 40. The liquefied mold compound flows through the channels 16 (as shown by arrows F) and into the substrate chambers 14 to surround the microelectronic devices 20 and drive out the air within the molding tool 10 through vents 18. The mold compound in the substrate chambers 14 forms a protective casing around each microelectronic device 20.

One drawback with the molding tool 10 described above is that it is difficult to avoid producing voids in the mold compound. Referring to FIG. 1B, for example, the mold compound flows around the outside edges of the devices 20 (as shown by arrows F1) and over the top of the devices 20 (as shown by arrows F2). Because of the limited clearance between the top of the devices 20 and the upper plate 12 (FIG. 1A), however, the mold compound tends to flow more slowly across the top of the devices 20 then around the sides of the devices 20. This can create voids 44 in the mold compound adjacent to the portions of the devices 20 farthest from the pellet cylinder 30. This problem can be exacerbated when the mold compound has a relatively high viscosity. Therefore, it would be desirable to improve the process for forming protective casings over microelectronic devices.

### BRIEF DESCRIPTION OF THE DRAWINGS

FIG. 1A is a partially schematic side cross-sectional view of a molding apparatus for encapsulating microelectronic devices in accordance with the prior art.

FIG. 1B is a partially schematic top plan view of the molding apparatus of FIG. 1A.

FIG. 2 is a side cross-sectional view of a microelectronic device before being packaged in accordance with several embodiments of the invention.

FIG. 3A is a top plan view of a molding apparatus for encapsulating a microelectronic device in accordance with an embodiment of the invention.

FIG. 3B is a partially schematic side cross-sectional view of the molding apparatus of FIG. 3A taken along lines 3B-3B.

FIG. 4A is a side cross-sectional view of a microelectronic device being packaged using the molding apparatus of FIGS. 3A and 3B in accordance with an embodiment of the invention.

FIG. 4B is a front cross-sectional view of a microelectronic device being packaged using the molding apparatus of FIGS. 3A and 3B in accordance with an embodiment of the invention.

FIG. 4C is a front cross-sectional view of the microelectronic device of FIG. 4A being packaged using the molding apparatus of FIGS. 3A and 3B in accordance with an embodiment of the invention.

FIG. 5 is a partially schematic side cross-sectional view of a molding apparatus for encapsulating a microelectronic device in accordance with another embodiment of the invention.

FIG. 6 is a top cutaway isometric view of a microelectronic device before being packaged in accordance with several embodiments of the invention.

FIG. 7 is a partially schematic side cross-sectional view of a molding apparatus for encapsulating a microelectronic device in accordance with yet another embodiment of the invention.

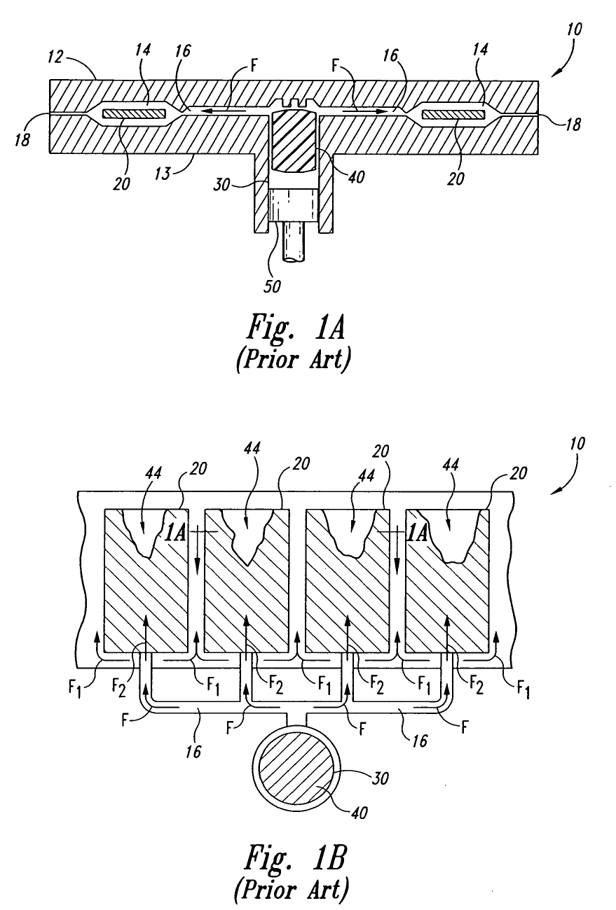

### DETAILED DESCRIPTION

A. Overview

The present invention is directed toward methods and apparatuses for encapsulating a microelectronic die or another type of microelectronic device. In one embodiment, a method for encapsulating a microelectronic device having a microelectronic die attached to a substrate includes positioning the microelectronic die in a molding cavity having a first volume. The method also includes introducing a molding compound into the molding cavity to at least partially encapsulate the die. The method further includes reducing the volume of the molding cavity from the first volume to a second volume less than the first volume while the microelectronic die and the molding compound are in the molding cavity.

Another embodiment of the invention is directed to a method of encapsulating a microelectronic device having a microelectronic die attached to a substrate. The die is positioned within a molding cavity between a first mold portion and a second mold portion. The method includes injecting a molding compound into the molding cavity. The method further includes reducing the volume of the molding cavity from a first volume to a second volume by moving at least one of the first mold portion and the second mold portion toward the other one of the first and second mold portions while the microelectronic die and the molding compound are in the molding cavity.

A further embodiment of the invention is directed to a method for encapsulating a plurality of microelectronic devices. The method includes positioning a first microelectronic die in a first molding cavity having a first volume and a second microelectronic die in a second molding cavity having a second volume. The method also includes injecting a molding compound into both the first molding cavity and the second molding cavity to at least partially encapsulate the first die and the second die, respectively. The method further includes reducing the volume of the first molding cavity from a first volume to a third volume less than the first volume and reducing the volume of the second molding cavity from a second volume to a fourth volume less than the second volume.

Another embodiment of the invention is directed to an apparatus for encapsulating a microelectronic device. The apparatus can include a first mold section and a second mold section facing the first mold section. The first and second mold sections define a cavity for receiving a microelectronic die attached to a substrate. At least one of the first and second mold sections is movable relative to the other one of the first and second mold sections to reduce a volume of the cavity from a first volume to a second volume less than the first volume after a molding compound is introduced into the cavity and at least partially encapsulates the die.

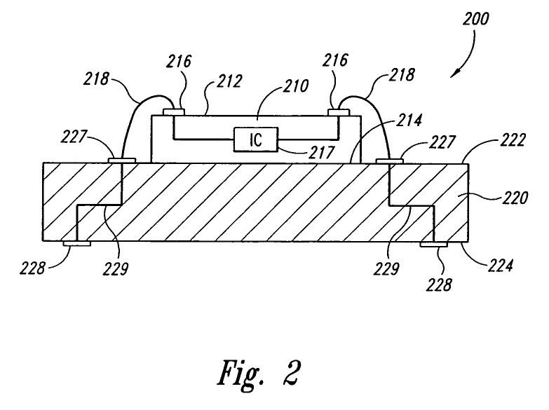

The present disclosure describes methods and apparatuses for encapsulating microelectronic devices. Many specific details of certain embodiments of the invention are set forth in the following description and in FIGS. 2-7 to provide a thorough understanding of these embodiments. One skilled in the art, however, will understand that the present invention may have additional embodiments, and that the invention can be practiced without several of the details described below.

B. Embodiments of Methods and Apparatuses for Encapsulating Microelectronic Devices

FIG. 2 is a side cross-sectional view of a microelectronic device 200 that is to be encapsulated in accordance with one embodiment of the invention. The microelectronic device 200 can include a microelectronic die 210 attached to a substrate 220. The microelectronic device 200 shown in FIG. 2 illustrates the die 210 and substrate 220 before encapsulating the die 210 with an encapsulation compound, such as a molding compound. The following description refers to encapsulating a microelectronic die on a flexible substrate, but it is expected that several embodiments of methods and molds in accordance the invention may be used to encapsulate a large variety of electrical and/or non-electrical articles. Therefore, aspects of the following description referring to encapsulating the microelectronic device 200 shown in FIGS. 2-7 are for purposes of illustration only, and are not intended to limit the scope of the invention.

The embodiment of the microelectronic die 210 shown in FIG. 2 includes a first side 212 and a second side 214 opposite the first side 212. The second side 214 of the die 210 is attached to the substrate 220. The microelectronic die 210 can also include a plurality of small contacts 216 and an integrated circuit 217 (shown schematically) coupled to the contacts 216. The contacts 216 are arranged in an array along the first side 212 of the microelectronic die 210. A plurality of wire-bonds 218 or other types of connectors couple the contacts 216 on the die 220 to corresponding contacts on the substrate 220.

The substrate 220 in the embodiment shown in FIG. 2 can include a first surface 222 and a second surface 224 opposite the first surface 222. The substrate 220 can be a flexible material or a generally rigid material. The substrate 220 is generally an interposing device that provides an array of ball-pads for coupling very small contacts on the microelectronic die 210 to another type of device. In the embodiment shown in FIG. 2, for example, the substrate 220 includes an array of terminal pads 227 on the first surface 222, an array of ball-pads 228 on the second surface 224, and a trace 229 or other type of conductive line between each terminal pad 227 and corresponding ball-pad 228. The ball-pads 228 are arranged in an array for surface mounting the device 200 to a board or module of another device. As such, the substrate 220 distributes signals from the very small contacts 216 on the die 210 to the larger array of ball-pads 228 on the second surface 224 of the substrate 220.

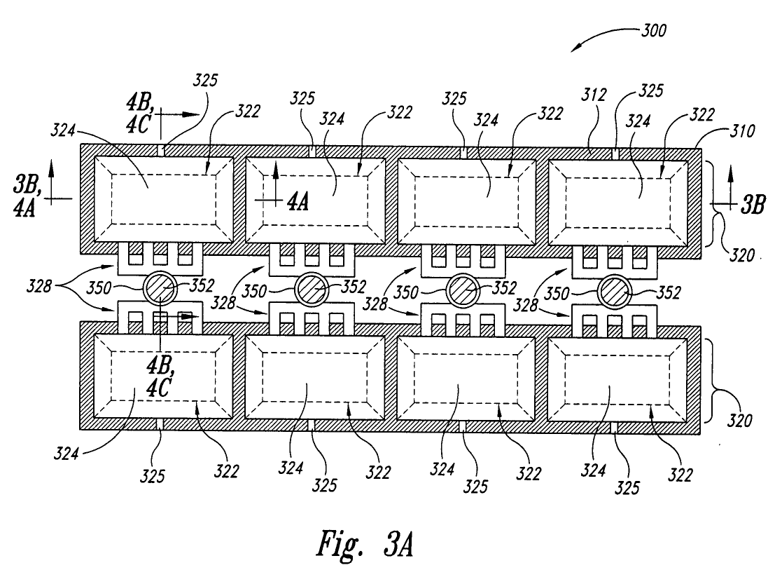

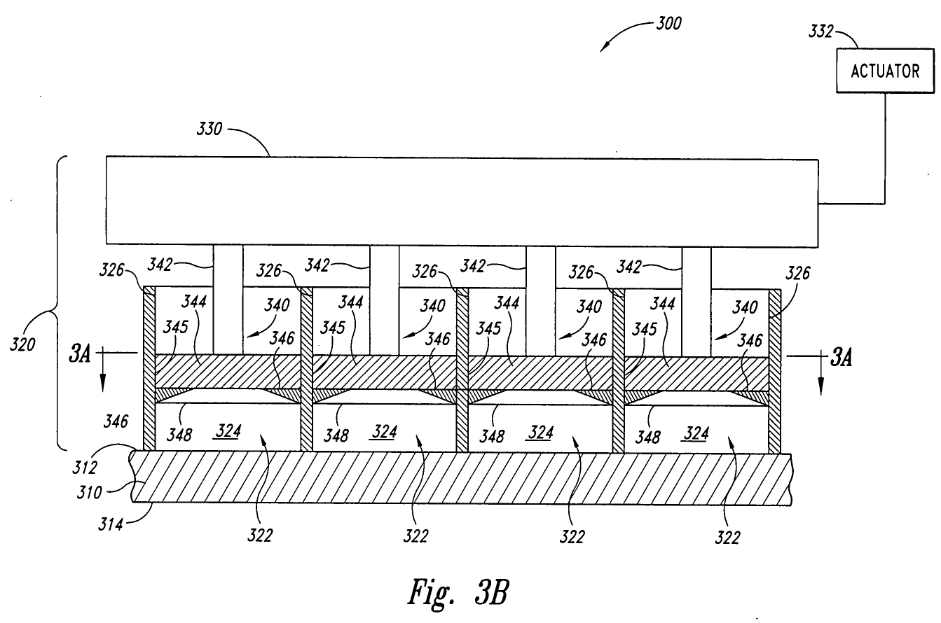

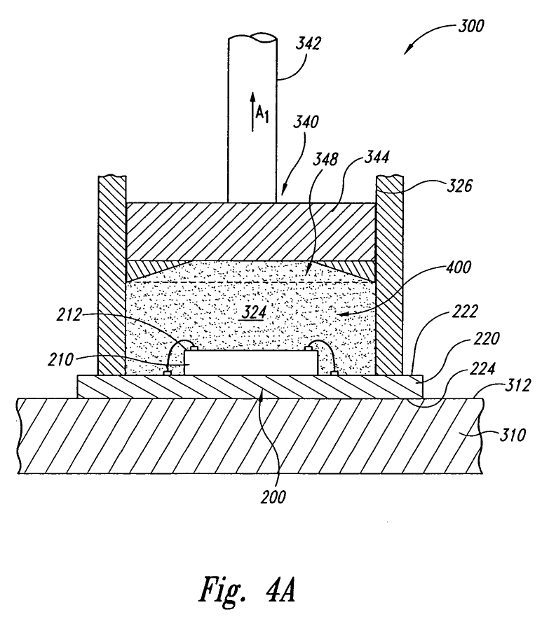

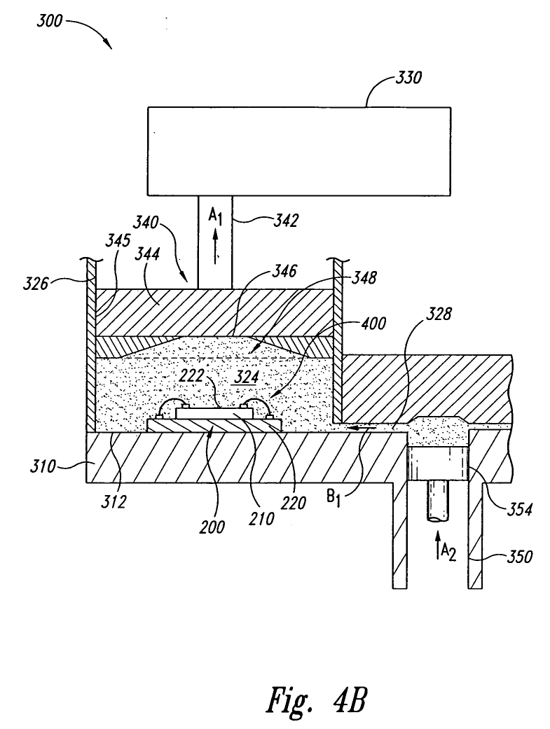

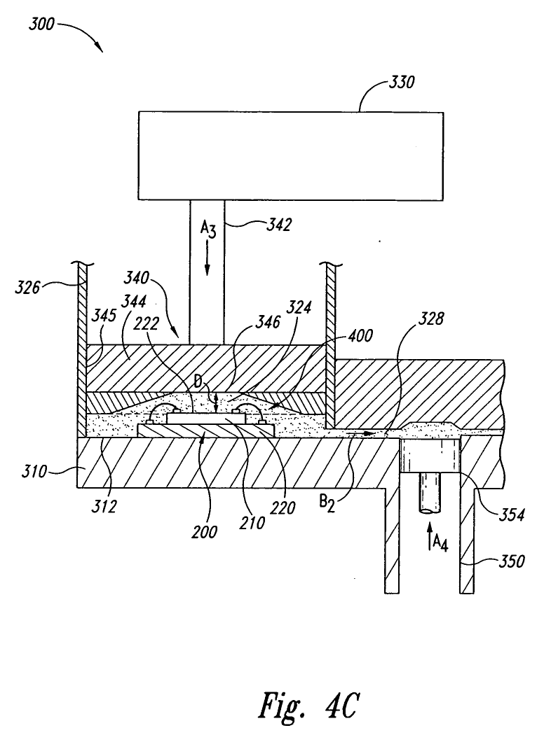

FIG. 3A is a top plan view of a molding apparatus 300 for encapsulating a microelectronic device (e.g., the microelectronic device 200 shown in FIG. 2). The molding apparatus 300 includes a first mold section 310 positioned below a second mold section 320 to form a plurality of internal chambers 322. The internal chambers 322 each include a cavity 324 that houses the device for encapsulation and one or more channel portions 328 in communication with the cavity 324. The molding apparatus 300 also includes a plurality of pellet cylinders 350 in communication with corresponding channel portions 328. A cylindrical pellet 352 formed of encapsulation material is compressed and liquefied within each pellet cylinder 350 by a piston (not shown) moving transversely to the plane of FIG. 3A. The encapsulation material then travels through the channel portions 328 to corresponding cavities 324. The operation of the pellet cylinders 350 is described in more detail below with respect to FIGS. 4B and 4C. The internal chambers 322 may also include a vent 325 for exhausting air and/or other gases from the apparatus 300 as the channel portions 328 and corresponding cavities 324 are filled with encapsulation material from the compressed and liquefied pellets 352. For purposes of illustration, eight internal chambers 322 are shown in FIG. 3A. The molding apparatus 300, however, can have a different number of internal chambers 322 and/or the arrangement of the apparatus 300 may be different.

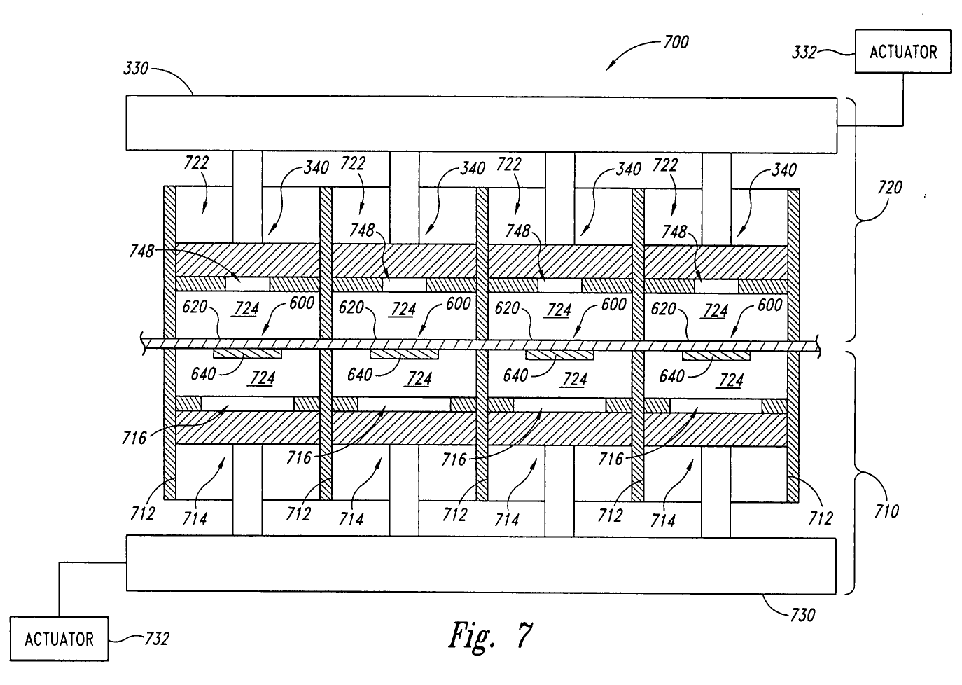

FIG. 3B is a side cross-sectional view of the molding apparatus 300 taken along lines 3B-3B of FIG. 3A. As best seen in FIG. 3B, the first mold section 310 of the molding apparatus 300 includes a first side 312 and a second side 314 opposite the first side 312. The first side 312 is a bearing surface for contacting the microelectronic device to be encapsulated (e.g., the second surface 224 of the substrate 220 shown in FIG. 2). In an embodiment of the invention discussed below with respect to FIG. 7, the first mold section can also include a cavity configured to form a protective casing over a portion of a device to be encapsulated.

The second mold section 320 of the molding apparatus 300 includes a plurality of cylinder portions 326 defined by a cylinder wall. Each cylinder portion 326 houses a first plunger 340 that is movable up and down within the cylinder portion 326 to define the cavity 324 below. The first plungers 340 each include a rod 342 attached to a plunger head 344. The individual heads 344 include a sidewall 345 adjacent to the walls of the corresponding cylinder 326 and an end wall 346 generally transverse to the sidewalls 345.

The end walls 346 of the first plungers 340 in the illustrated embodiment include interchangeable cavity inserts 348. The interchangeable cavity inserts 348 can be selected based on the particular configuration of the device to be encapsulated and, more particularly, on the desired final shape of the protective casing over the device. In the molding apparatus 300 illustrated in FIGS. 3A and 3B, for example, the cavity inserts 348 include a generally planar portion having tapered sidewalls. In other embodiments, the interchangeable cavity inserts 348 may have different configurations and/or the end walls 346 of the first plungers 340 may not include interchangeable cavity inserts.

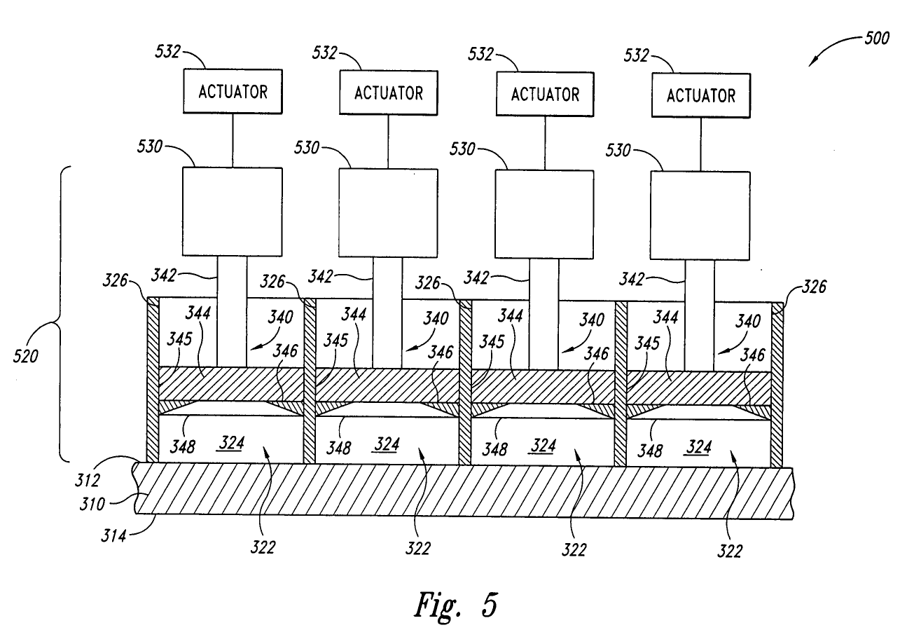

The molding apparatus 300 also includes a support member 330 operably coupled to an actuator 332 (shown schematically) and carrying at least one of the first plungers 340. The actuator 332 can include a hydraulic motor, a servo motor, or another type of actuating device. The support member 330 is configured to move the first plungers 340 axially within the corresponding cylinder portions 326 during the encapsulation process. The movement of the first plungers 340 during encapsulation is described in more detail below with respect to FIGS. 4A-4C. In the illustrated embodiment, the first plungers 340 are ganged together for operation. In another embodiment described below with respect to FIG. 5, the first plungers 340 may be configured to move independently with respect to each other.

FIGS. 4A-4C illustrate an embodiment of a method for encapsulating a microelectronic device in a manner that reduces or eliminates voids in the protecting casing formed over the device. More specifically, FIG. 4A is a partial side cross-sectional view and FIGS. 4B and 4C are partial front cross-sectional views illustrating the microelectronic device 200 being encapsulated using the molding apparatus 300 described above with respect to FIGS. 3A and 3B. Although only a single cylinder 326 is shown in FIGS. 4A-4C, the method can be used to encapsulate a plurality of devices simultaneously.

Referring first to FIG. 4A, the device 200 is positioned within the cavity 324 such that the first side 312 of the first mold section 310 presses against the second surface 224 of the substrate 220. If necessary, the first plunger 340 can be retracted a given distance (as shown by arrow A₁) to provide sufficient clearance between the end wall 346 of the first plunger 340 and the first side 212 of the die 210. A molding compound 400 is then introduced into the cavity 324 to at least partially encapsulate the device 200.

Referring to FIG. 4B, the molding compound 400 is provided to the cavity 324 via the channel portion 328 and the pellet cylinder 350 described above with respect to FIG. 3A. In the illustrated embodiment, for example, a second plunger 354 of the pellet cylinder 350 is moved upwardly (as shown by arrow A₂) to compress and liquefy the cylindrical pellet 352 (FIG. 3A) formed of molding compound 400. The molding compound 400 can include a high temperature, humidity-resistant thermoset material, such as an epoxy resin. The epoxy resin may have a variety of formulations suitable for encapsulating microelectronic devices. The molding compound 400 flows through the channel portion 328 (as shown by arrow B₁) to at least partially fill the cavity 324 and encapsulate at least a portion of the device 200. In the illustrated embodiment, the cavity 324 is completely filled with the molding compound 400. In other embodiments, however, the cavity 324 may not be completely filled.

Referring next to FIG. 4C, an embodiment of the method for encapsulating the microelectronic device 200 includes reducing the volume of the cavity 324 from a first volume to a second volume less than the first volume. More particularly, the first plunger 340 is moved downwardly (as shown by the arrow A₃) and stopped at a distance D from the device 200. In one embodiment, for example, the cavity insert 348 of the first plunger 340 is stopped at a distance from the first side 212 of the die 210 corresponding to a specified mold cap thickness required for the finished microelectronic device package. In other embodiments, the first plunger 340 may be stopped at a different distance from the die 210.

In several embodiments, a portion of molding compound 400 can flow out of the cavity 324 and back into the channel portion 328 toward the pellet cylinder 350 (as shown by arrow B₂) after the volume of the cavity 324 is reduced from the first volume to the second volume. In such cases, the second plunger 354 can subsequently be moved upwardly (as shown by arrow A₄) within the pellet cylinder 350 to further compress the molding compound 400 within the internal chamber 322. This additional pressure can help eliminate any remaining voids within the molding compound 400. In alternative embodiments, the first and second plungers 340 and 354 can move simultaneously during the encapsulation process.

One advantage of embodiments of the molding apparatus 300 and the method described above with reference to FIGS. 4A-5B is that it is expected to reduce or eliminate voids in the protective casing over the microelectronic device 200. As described previously, conventional molding tools have a limited clearance between the top of device to be encapsulated and the top plate of the molding cavity. This often results in voids and/or irregularities in the protective casing over the device. The molding apparatus 300 and method described above, however, include first plungers 340 that are movable within the individual cylinders 326 to provide sufficient clearance between the top of the devices and the cavity inserts 348 during encapsulation, which can minimize or eliminate voids in the finished packages over the microelectronic devices. Furthermore, the volume reduction of the cavities 324 can mitigate or eliminate filler concentrations inherent in thin cap molding that affect marking and package cosmetics. For example, in cases where the molding compound 400 includes one or more fillers, the reduction in volume within the cavities 324 can reduce the likelihood that the fillers within the molding compound 400 become concentrated in some areas.

C. Additional Embodiments of Methods and Apparatuses for Encapsulating Microelectronic Devices

FIG. 5 is a side cross-sectional view of a molding apparatus 500 configured in accordance with another embodiment of the invention. The apparatus 500 can include several features generally similar to the molding apparatus 300 described above. Accordingly, like reference numbers refer to like components in FIGS. 3A and 3B and FIG. 5.

The apparatus 500 in the illustrated embodiment includes the first mold section 310 positioned below a second mold section 520. The second mold section 520 can be generally similar to the second mold section 320 described above with respect to FIGS. 3A and 3B, however, the individual first plungers 340 in this embodiment are not ganged together. Rather, the apparatus 500 includes a plurality of support members 530 operably coupled to corresponding actuators 532 (shown schematically). The support members 530 are each coupled to a corresponding first plunger 340. In this way, the first plungers 340 may be configured to move independently of each other. For example, a plurality of microelectronic devices having different configurations and/or different process specifications for the protective casing may be encapsulated simultaneously within the molding apparatus 500. In a particular example, one first plunger 340 may be at a different speed than an adjacent first plunger 340 because different molding compounds are used within the respective cavities 324.

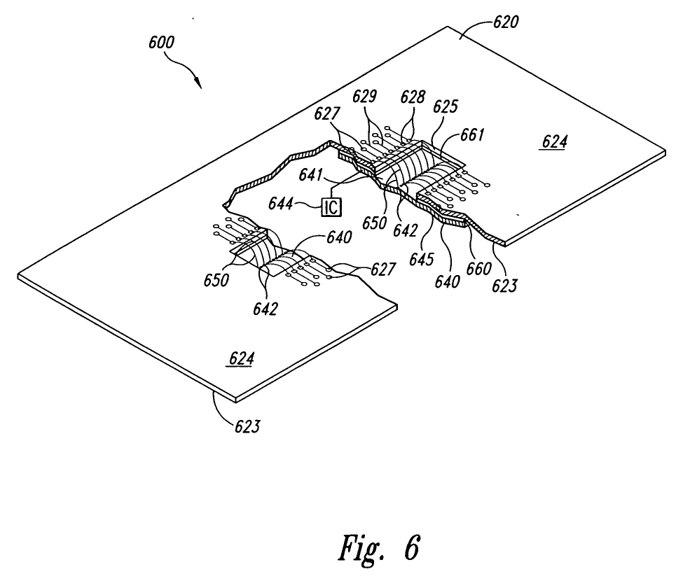

FIG. 6 is a top cutaway isometric view of a microelectronic device 600 that is to be encapsulated in accordance with still another embodiment of the invention. The microelectronic device 600 can include a substrate 620 and a microelectronic die 640 attached to the substrate 620 by an adhesive 660. The microelectronic device 600 shown in FIG. 6 illustrates the substrate 620 and the die 640 before encapsulating the die.

The substrate 620 in the illustrated embodiment includes a first surface 623 and a second surface 624 opposite the first surface 623. The substrate 620 can also include an elongated slot 625 between the first and second surfaces 623 and 624 that extends lengthwise along a medial portion of the substrate 620. The substrate 620 is generally an interposing device that provides an array of ball-pads for coupling very small contacts on the microelectronic die to another type of device. In the embodiment shown in FIG. 6, for example, the substrate 620 includes a first array of ball-pads 627, a second array of terminal pads 628 proximate to the slot 625, and a trace 629 or other type of conductive line between each ball-pad 627 and corresponding terminal pad 628. The substrate 620 can be a flexible material or a substantially rigid material, and the traces 629 can be conductive lines that are printed on the substrate in a manner similar to printed circuit boards.

The embodiment of the microelectronic die 640 shown in FIG. 6 includes a first side 641 attached to the first surface 623 of the substrate 620 by the adhesive 660. The adhesive 660 can be a two-sided tape or a decal adhered to the first surface 623 of the substrate 620 adjacent to the sides of the slot 625. The microelectronic die 640 can also include a plurality of small contacts 642 and an integrated circuit 644 (shown schematically) coupled to the contacts 642. The contacts 642 are arranged in an array along the first side 641 of the microelectronic die 640 so that the contacts 642 are aligned with or otherwise accessible through the slot 625 in the substrate 620. A plurality of wire-[bonds 650 or other types of connectors couple the contacts 642 of the die 640 to corresponding terminal pads 628 on the substrate 620. As such, the substrate 620 distributes signals from the very small contacts 642 to the larger array of ball-pads 627.

FIG. 7 is a side cross-sectional view of a molding apparatus 700 for encapsulating a microelectronic device (e.g., the device 600) in accordance with yet another embodiment of the invention. The molding apparatus 700 includes a first mold section 710 positioned below a second mold section 720 to form a plurality of internal chambers 722. The internal chambers 722 each include a cavity 724 that houses a device for encapsulation. The molding apparatus 700 differs from the molding apparatus 300 described above in that the first mold section 710 also includes a plurality of cylinder portions 712 defined by cylinder walls that each house third plungers 714 for further compressing a molding compound within the individual molding cavities 724. The third plungers 714 are all carried by a support member 730, which is operably coupled to an actuator 732. The support member 730 and actuator 732 can be generally similar to the support member 330 and actuator 332 described above with respect to FIG. 3B.

The first plungers 340 and third plungers 714 can both move (either simultaneously or independently) during the encapsulation process to reduce the volume of the portion of the cavity 724 on either side of the device 600 being encapsulated. In this way, for example, voids can be reduced or eliminated in protective casings over the device 600 (which includes a protective casing over both the first surface 623 and the second surface 624 as shown in FIG. 6).

In another aspect of this embodiment, the first plungers 340 and the third plungers 714 each include cavity inserts corresponding to a selected configuration for the protective casing over the devices 600 to be encapsulated. In the illustrated embodiment, for example, the first plungers 340 include cavity inserts 748 configured to form a first casing that fills the slot 625 (FIG. 6) and covers the terminal pads 628 (FIG. 6) on the individual substrates 620, and the third plungers 714 include cavity inserts 716 configured to form a second casing over the die 640 and a portion of the first surface 623 (FIG. 6) of the substrate 620. In other embodiments, the cavity inserts may have different configurations based on the devices being encapsulated and/or the desired configuration of the protective casings over the devices.

From the foregoing, it will be appreciated that specific embodiments of the invention have been described herein for purposes of illustration, but that various modifications may be made without deviating from the invention. For example, the cylinders and/or the cavities may have different configurations than those described above. Aspects of the invention described in the context of particular embodiments may be combined or eliminated in other embodiments. For example, the molding apparatuses in any of the foregoing embodiments can be used to encapsulate microelectronic devices other than those described above. Further, while advantages associated with certain embodiments of the invention have been described in the context of those embodiments, other embodiments may also exhibit such advantages, and not all embodiments need necessarily exhibit such advantages to fall within the scope of the invention. Accordingly, the invention is not limited, except as by the appended claims.

I/We claim:

1. A method of encapsulating a microelectronic device having a microelectronic die attached to a substrate, the method comprising:
positioning the microelectronic die in a molding cavity having a first volume;
introducing a molding compound into the molding cavity to at least partially encapsulate the die; and
reducing the volume of the molding cavity from the first volume to a second volume less than the first volume while the microelectronic die and the molding compound are in the molding cavity.

2. The method of claim 1 wherein:
positioning the microelectronic die in a molding cavity comprises positioning the die in the cavity between a first mold portion and a second mold portion; and
reducing the volume of the molding cavity from the first volume to the second volume comprises moving at least one of the first or second mold portions toward the other one of the first or second mold portions.

3. The method of claim 2 wherein the first mold portion is fixed and wherein reducing the volume of the molding cavity comprises moving the second mold portion toward the first mold portion.

4. The method of claim 2 wherein the first mold portion is fixed and wherein reducing the volume of the molding cavity comprises moving the second mold portion toward the first mold portion until the second mold portion is spaced apart from the die by a separation distance corresponding to a desired mold thickness.

5. The method of claim 2 wherein reducing the volume of the molding cavity comprises moving both the first mold portion and the second mold portion toward each other simultaneously.

6. The method of claim 1, further comprising driving at least a portion of the molding compound out of the molding cavity while reducing the volume of the molding cavity from the first volume to the second volume.

7. The method of claim 1 wherein introducing a molding compound into the molding cavity comprises injecting the molding compound into the molding cavity.

8. The method of claim 1 wherein introducing a molding compound into the molding cavity comprises completely filling the molding cavity with the molding compound before reducing the volume of the molding cavity from the first volume to the second volume.

9. The method of claim 1 wherein positioning the microelectronic die in a molding cavity comprises positioning the die in the cavity between a first mold portion having a cavity insert and a second mold portion.

10. The method of claim 9, further comprising selecting the cavity insert based on the particular configuration of the microelectronic device.

11. The method of claim 9 wherein the cavity insert is a first cavity insert and the second mold portion includes a second cavity insert, and wherein the method further comprises selecting the first cavity insert and the second cavity insert based on the particular configuration of the microelectronic device.

12. A method of encapsulating a microelectronic device having a microelectronic die attached to a substrate, the die being positioned within a molding cavity between a first mold portion and a second mold portion, the method comprising:
injecting a molding compound into the molding cavity; and
reducing the volume of the molding cavity from a first volume to a second volume by moving at least one of the first mold portion and the second mold portion toward the other one of the first and second mold portions while the microelectronic die and the molding compound are in the molding cavity.

13. The method of claim 12 wherein the first mold portion is fixed and wherein reducing the volume of the molding cavity comprises moving the second mold portion along an axis toward the first mold portion.

14. The method of claim 12 wherein the first mold portion is fixed and wherein reducing the volume of the molding cavity comprises axially moving the second mold portion along an axis toward the first mold portion until the second mold portion is spaced apart from the die by a separation distance corresponding to a desired mold thickness.

15. The method of claim 12 wherein reducing the volume of the molding cavity comprises moving both the first mold portion and the second mold portion toward each other simultaneously.

16. The method of claim 12, further comprising driving at least a portion of the molding compound out of the molding cavity while reducing the volume of the molding cavity from the first volume to the second volume.

17. A method of encapsulating a microelectronic device having a microelectronic die and a substrate, the method comprising:
positioning the microelectronic die within a molding cavity defined at least in part by a first mold portion and a second mold portion, wherein the substrate is carried by the first mold portion and the die is facing the second mold portion;
injecting a molding compound into the molding cavity to at least partially encapsulate the die; and
moving the second mold portion from a first position spaced apart from a top surface of the die to a second position closer to the top surface.

18. The method of claim 17 wherein moving the second mold portion from the first position to the second position reduces a volume of the molding cavity from a first volume to a second volume less than the first volume.

19. The method of claim 17 wherein moving the second mold portion comprises moving the second mold portion toward the die until the second mold portion is spaced apart from the die by a separation distance corresponding to a desired mold thickness.

20. The method of claim 17 wherein injecting a molding compound into the molding cavity comprises completely filling the molding cavity with the molding compound before moving the second mold portion from the first position to the second position.

21. The method of claim 17 wherein the die is a first die and the molding cavity is a first molding cavity, and wherein the method further comprises:
positioning a second microelectronic die in a second molding cavity defined by a third mold portion and a fourth mold portion;
injecting a molding compound into the second molding cavity to at least partially encapsulate the second die; and
moving the fourth mold portion toward the second die.

22. The method of claim 21 wherein moving the second mold portion toward the first die and moving the fourth mold portion toward the second die occur simultaneously.

23. The method of claim 21 wherein moving the second mold portion toward the first die and moving the fourth mold portion toward the second die does not occur simultaneously.

24. A method for encapsulating a plurality of microelectronic devices, the method comprising:
positioning a first microelectronic die in a first molding cavity having a first volume and positioning a second microelectronic die in a second molding cavity having a second volume;
injecting a molding compound into the first molding cavity to at least partially encapsulate the first die and injecting a molding compound into the second molding cavity to at least partially encapsulate the second die;
reducing the volume of the first molding cavity from a first volume to a third volume less than the first volume; and
reducing the volume of the second molding cavity from a second volume to a fourth volume less than the second volume.

25. The method of claim 24 wherein reducing the volume of the first molding cavity and reducing the volume of the second molding cavity occur simultaneously.

26. The method of claim 24 wherein reducing the volume of the first molding cavity does not occur at the same time as reducing the volume of the second molding cavity.

27. The method of claim 24 wherein:
positioning the first microelectronic die in the first molding cavity comprises positioning the first die in the first molding cavity between a first mold portion and a second mold portion;
reducing the volume of the first molding cavity from the first volume to the second volume comprises moving at least one of the first or second mold portions toward the other one of the first or second mold portions;
positioning the second microelectronic die in the second molding cavity comprises positioning the second die in the second molding cavity between a third mold portion and a fourth mold portion; and
reducing the volume of the second molding cavity from the third volume to the fourth volume comprises moving at least one of the third or fourth mold portions toward the other one of the third or fourth mold portions.

28. The method of claim 27 wherein:
the first mold portion is fixed and reducing the volume of the first molding cavity comprises moving the second mold portion toward the first mold portion until the second mold portion is spaced apart from the first die by a desired distance; and
the third mold portion is fixed and reducing the volume of the second molding cavity comprises moving the fourth mold portion toward the third mold portion until the fourth mold portion is spaced apart from the second die by a desired distance.

29. An apparatus for encapsulating a microelectronic device, the apparatus comprising:
a first mold section; and
a second mold section facing the first mold section, the first and second mold sections defining at least a portion of a cavity for receiving a microelectronic die attached to a substrate, wherein at least one of the first and second mold sections is movable relative to the other one of the first and second mold sections to reduce a volume of the cavity from a first volume to a second volume less than the first volume while both a molding compound and the die are in the cavity.

30. The apparatus of claim 29 wherein:
the first mold section is fixed; and
the second mold section is movable from a first position to a second position, the cavity having the first volume when the second mold section is in the first position and the second volume less than the first volume when the second mold section is in the second position.

31. The apparatus of claim 29 wherein:
the first mold section has a first surface and a second surface opposite the first surface, the first surface including a bearing surface configured to carry the substrate; and
the second mold section includes a cylinder aligned with the bearing surface of the first mold section and a plunger positioned within the cylinder and movable within the cylinder in an axial direction between a first position and a second position to define the cavity, the plunger having a sidewall aligned with the axial direction and an end wall transverse to the axial direction, at least a portion of the end wall being generally transverse to the sidewall.

32. The apparatus of claim 31 wherein the cavity has the first volume when the plunger is in the first position and the second volume less than the first volume when the plunger is in the second position.

33. The apparatus of claim 31, further comprising:
a support member carrying the plunger; and
an actuator operably coupled to the support member and configured to move the plunger in the axial direction.

34. The apparatus of claim 29 wherein:
the first mold section includes a first cylinder aligned with the die attached to the substrate and a first plunger positioned within the first cylinder and movable within the first cylinder in an axial direction between a first position and a second position to define a first portion of the cavity, the first plunger having a first sidewall aligned with the axial direction and a first end wall transverse to the axial direction, at least a portion of the first end wall being generally transverse to the first sidewall; and
the second mold section includes a second cylinder aligned with the first cylinder of the first mold section and a second plunger positioned within the second cylinder and movable within the second cylinder in the axial direction between a third position and a fourth position to define a second portion of the cavity, the second plunger having a second sidewall aligned with the axial direction and a second end wall transverse to the axial direction, at least a portion of the second end wall being generally transverse to the second sidewall.

35. The apparatus of claim 34 wherein the cavity has a first volume when the first plunger is in the first position and third plunger is in the third position and the cavity has a second volume less than the first volume when the first plunger is in the second position and the second plunger is in the fourth position.

36. The apparatus of claim 34, further comprising:
a first support member carrying the first plunger and a second support member carrying the second plunger; and
a first actuator operably coupled to the first plunger and a second actuator coupled to the second plunger, the first and second actuators being configured to move the first and second plungers, respectively, in the axial direction.

37. The apparatus of claim 29 wherein at least one of the first and second mold sections further comprises a cavity insert, the cavity insert being selected in accordance with the particular configuration of the microelectronic die.

38. The apparatus of claim 29 wherein the first mold section and the second mold section are within a mold body, and wherein the mold body comprises:
a chamber in the mold body having a first portion in communication with the cavity and a second portion spaced apart from the first portion; and
a pellet plunger positioned in the second portion of the chamber and movable within the second portion of the chamber in an axial direction between a first position and a second position to inject the molding compound from the chamber into the cavity.

39. An apparatus for packaging a plurality of microelectronic devices having microelectronic dies attached to substrates, the apparatus comprising:
a first mold portion; and
a second mold portion facing the first mold portion, the first and second mold portions defining a plurality of chambers for receiving individual dies, wherein the individual chambers include at least one plunger positioned in the chamber and movable between a first position and a second position to at least partially define a molding cavity, the individual cavities having a first volume when the at least one plunger is in the first position and a second volume less than the first volume when the at least one plunger is in the second position.

40. The apparatus of claim 39 wherein:
the first mold portion has a first surface and a second surface opposite the first surface, the first surface including a bearing surface configured to carry the substrates; and
the second mold portion includes (a) a plurality of cylinders aligned with the bearing surface of the first mold portion, and (b) a plunger positioned within each cylinder and movable within the cylinder in an axial direction between the first position and the second position.

41. The apparatus of claim 40, further comprising a support member carrying the individual plungers and an actuator operably coupled to the support member and configured to move the plungers from the first position to the second position.

42. The apparatus of claim 41 wherein the individual plungers move simultaneously with respect to each other.

43. The apparatus of claim 41 wherein the individual plungers move independently with respect to each other.

44. The apparatus of claim 40 wherein the individual plungers within each cylinder include a sidewall aligned with the axial direction and an end wall transverse to the axial direction, at least a portion of the end wall being generally transverse to the sidewall.

45. The apparatus of claim 40 wherein the individual plungers within each cylinder include a cavity insert, the cavity insert being selected in accordance with the particular configuration of the microelectronic dies.
